(19) United States
(12) Patent Application Publication
(10) Pub. No.: US 2008/0248626 A1
(43) Pub. Date: Oct. 9, 2008

(54) SHALLOW TRENCH ISOLATION SELF-ALIGNED TO TEMPLATED RECRYSTALLIZATION BOUNDARY

(75) Inventors: Yaocheng Liu, Elmsford, NY (US); Zhijiong Luo, Carmel, NY (US); Katherine L. Saenger, Ossining, NY (US); Chun-Yung Sung, Poughkeepsie, NY (US); Rajasekhar Venigalla, Wappingers Falls, NY (US); Haizhou Yin, Poughkeepsie, NY (US)

Correspondence Address: SCULLY, SCOTT, MURPHY & PRESSER, P.C., 400 GARDEN CITY PLAZA, SUITE 300, GARDEN CITY, NY, 11530, US

(73) Assignee: INTERNATIONAL BUSINESS MACHINES CORPORATION, Armonk, NY (US)

(21) Appl. No.: 11/697,102

(22) Filed: Apr. 5, 2007

(51) Int. Cl. H01L 21/762

(52) U.S. Cl. 438/424; 257/E21.546

(57) ABSTRACT

A hybrid orientation direct-semiconductor-bond (DSB) substrate with shallow trench isolation (STI) that is self-aligned to recrystallization boundaries is formed by patterning a hard mask layer for STI, a first amorphization implantation into openings in the hard mask layer, lithographic patterning of portions of a top semiconductor layer, a second amorphization implantation into exposed portions of the DSB substrate, recrystallization of the portions of the top semiconductor layer, and formation of STI utilizing the pattern in the hard mask layer. The edges of patterned photoresist for the second amorphization implantation are located within the openings in the patterned hard mask layer. Defective boundary regions formed underneath the openings in the hard mask layer are removed during the formation of STI to provide a leakage path free substrate. Due to elimination of a requirement for increased STI width, device density is increased compared to non-self-aligning process integration schemes.

### FIELD OF THE INVENTION

The present invention relates to a semiconductor structure, and particularly to methods of manufacturing a semiconductor structure with shallow trench isolation that is self-aligned to a templated recrystallization boundary in direct-semiconductor-bond substrates.

### BACKGROUND OF THE INVENTION

To improve device performance of a metal-oxide-semiconductor field effect transistor (MOSFET), and especially to increase the on-current, various methods of increasing the minority carrier mobility have been investigated. Among these, the strong dependence of minority carrier mobility on silicon surface orientation has led to hybrid orientation technology (HOT) semiconductor substrates in which different types of MOSFETs are formed on semiconductor surfaces with different surface orientations. Yang et al., “High Performance CMOS Fabricated on Hybrid Substrate with Different Crystal Orientations,” IEDM Tech. Dig., 2003, pp. 18.7.1-18.7.4 (2003) and U.S. Patent Application Publication No. 2004/0256700 to Doris et al. disclose a hybrid substrate semiconductor structure in which n-type MOSFETs are formed in silicon with a (100) surface orientation (the orientation in which electron mobility is the highest) and p-type MOSFETs are formed in silicon with a (110) surface orientation (the orientation in which hole mobility is the highest). One type of MOSFETs is formed on a semiconductor-on-insulator structure while the other type of MOSFETs is formed on a portion of the substrate that is epitaxially regrown from a handle wafer.

Further, U.S. Patent Application Publication No. 2005/0116290 to de Souza et al. discloses amorphization-templated recrystallization (ATR) methods for fabricating hybrid orientation substrates on direct-semiconductor-bond (DSB) substrates, which are formed by bonding a first semiconductor surface on a first semiconductor substrate to a second semiconductor surface on a second semiconductor substrate followed by either cleaving or polishing of one of the two semiconductor substrates. According to de Souza et al., a first semiconductor layer having a first surface orientation is directly bonded to a second semiconductor layer having a second surface orientation that is different from the first orientation. Selected areas of the first semiconductor layer are amorphized by ion implantation, and then recrystallized into a crystalline structure with the orientation of the second semiconductor layer using the second semiconductor layer as a recrystallization template.

Sequential top-down views of an exemplary prior art structure according to a “top amorphization/bottom templating” version of the prior art ATR method for forming a bulk hybrid orientation Si substrate are shown in FIGS. 1A-5A. Corresponding sequential vertical cross-sections along the plane B-B′ in FIGS. 1A-5A are shown in FIGS. 1B-5B.

Referring to FIGS. 1A and 1B, there is shown a direct-semiconductor-bond (DSB) substrate with a bottom semiconductor layer 10, a top semiconductor layer 20, and a bonded interface 15. The bottom semiconductor layer 10 and the top semiconductor layer 20 have different surface orientations, that is, the crystallographic orientations in the direction of the surface normal of the outer surface 19 of the top semiconductor layer 20.

Referring to FIGS. 2A and 2B, deposition of pad layers, lithographic patterning, etching of the top semiconductor layer 20 and the bottom semiconductor layer 10 are sequentially employed to form a shallow trench followed by deposition of shallow trench isolation material and planarization to form shallow trench isolation 30 in the top semiconductor layer 20 and in an upper portion of the bottom semiconductor layer 10.

Referring to FIGS. 3A and 3B, an amorphization implant is performed into a portion of the DSB substrate to form an amorphized region 21 such that the area of the amorphized region 21 encompasses an active area surrounded by the shallow trench isolation 30. The depth of the amorphized region 21 exceeds the thickness of the top semiconductor layer 20. The amorphizing ion implant is typically performed with Si or Ge ions.

Referring to FIGS. 4A and 4B, the amorphized region 21 is then recrystallized into a crystalline structure using the lower silicon layer 10 as a recrystallization template. The resulting structure comprises an epitaxially aligned semiconductor material in most of the volume of the amorphized region 21, which in conjunction with the original unamorphized portion of the lower substrate 10 form an extended lower semiconductor layer 11. The semiconductor material in the extended lower semiconductor layer 11 is epitaxially aligned with the same crystallographic orientations as the original lower semiconductor layer 10. The surface of the recrystallized semiconductor structure comprises a first portion with the surface orientation of the original top semiconductor layer 20 and a second portion with the surface orientation of the original bottom semiconductor layer 10. Thus, a bulk hybrid orientation substrate is obtained.

Instead of an idealized structure which consists of only the original surface orientations of the top semiconductor layer 20 and the bottom semiconductor layer 10, a typical semiconductor structure at this stage also comprises a trench-edge defect region 12, which contains trench-edge defects. These trench-edge defects, associated with slow-growing (111) planes encountered during recrystallization, have been described in K. L. Saenger et al., “A study of trench-edge defect formation in (001) and (011) silicon recrystallized by solid phase epitaxy,” J. Appl. Phys. Vol. 101 N2 pp. 024908-1˜024908-8 (2007). These trench-edge defects are very stable and cannot be removed even by an anneal at 1325° C. for 5 hours.

Referring to FIGS. 5A and 5SB, a gate dielectric 40 is formed and a gate line 42 is patterned by deposition of a gate stack, lithographic patterning, and etch of the gate stack. After suitable implants, spacer formation, and contact formation, MOSFETs are formed on the top semiconductor layer 20 and on the extended bottom semiconductor layer 11.

As discussed in U.S. patent application Ser. No. 11/142,646, semiconductor area with these trench-edge defect region 12 is not suitable for high performance MOSFETs, of which the geometry requires a gate line 42 to cross over the trench-edge defect region 12 as shown in FIG. 5A. This is because the portion of the trench-edge defect region 12 that is located under the gate line 42 provides a potentially low-resistance leakage path between the source and drain of a MOSFET.

As further described in U.S. Patent Application Publication No. 2006/0276011 to Fogel et al., ATR process sequences in which the STI patterning is performed after ATR may be used to avoid generation of trench-edge defect regions that are encountered in “ATR-after-STI” process sequences. While these “ATR-before-STI” alternatives offer the advantage of etching defective boundary regions between changed-orientation regions and original-orientation regions and forming shallow trench isolation (STI) therein, the formation of the STI is not self-aligned to an ATR implantation mask. Consequently, the STI is not self-aligned to the defective boundary regions. In order to completely remove the defective boundary regions, the width of the STI must be greater than the sum of the width of the defective boundary region, which is typically about the thickness of the amorphized region in a direct semiconductor bond (DSB) substrate, the overlay tolerance of the amorphization mask, and the overlay tolerance of the STI mask. The two overlay tolerances are substantial relative to the thickness of the amorphized region. For example, the thickness of the amorphized region may be about 80 nm and the overlay tolerances of the two masks may be 60 nm respectively even with deep ultraviolet (DUV) masks. This approach forces the width of the STI to be greater than the critical dimension of advanced lithographic tools, and also greater than the minimum dimensions of STI that can be otherwise manufactured.

Therefore, there exists a need for methods of forming a semiconductor structure in which the width of STI is not required to be greater than the dimension allowed by processing constraints, such as critical dimension of lithographic tools or limitations in gap fill process, and trench-edge defect regions and defective boundary regions are avoided or removed.

Further, there exists a need for methods of forming a hybrid orientation direct-semiconductor-bond substrate in which shallow trench isolation area may be minimized and device density may be maximized, while the defect regions associated with formation of the hybrid orientation are minimized.

### SUMMARY OF THE INVENTION

The present invention addresses the needs described above by providing methods for manufacturing a semiconductor structure on a direct-semiconductor-bond substrate in which defective boundary regions are formed during a recrystallization of portions of the substrate and shallow trench isolation is formed self-aligned to the defective boundary region.

Specifically, the present invention forms a hard mask layer on a direct-semiconductor-bond substrate and patterns the hard mask layer for shallow trench isolation. The amorphization implantation mask, and consequently, the amorphization implant region are aligned to the patterns in the hard mask layer for shallow trench isolation. Defective boundary regions, formed between the boundaries between original-orientation region and changed-orientation regions after a recrystallization anneal, are also aligned to the patterns in the hard mask layer. Shallow trench isolation regions are etched utilizing the patterned hard mask layer to form shallow trenches, which is then filled with a dielectric material and planarized to form shallow trench isolation. Since the shallow trench isolation is also aligned to the original patterns in the hard mask layer, the shallow trench isolation is self-aligned to the defective boundary regions.

According to the present invention, a method of forming a semiconductor structure comprises:

providing a direct-semiconductor-bond (DSB) substrate containing a top semiconductor layer with a first surface orientation and a bottom semiconductor layer with a second surface orientation;

forming a hard mask layer on the top semiconductor layer;

lithographically patterning the hard mask layer with a shallow trench isolation (STI) pattern, wherein the STI pattern contains at least one opening;

implanting at least one first amorphization implant species into the top semiconductor layer through at least one opening in the hard mask layer;

applying and lithographically patterning a photoresist on the DSB substrate, wherein at least one edge of the photoresist is located within the at least one opening in the hard mask layer; and

implanting at least one second amorphization implant species into portions of the top semiconductor layer that is not covered with the photoresist.

According to the present invention, the lithographical patterning of the photoresist on the DSB substrate is aligned to the STI pattern in the hard mask layer. The implanting of the at least one first amorphization implant species forms at least one amorphization boundary region extending from a top surface of the DSB substrate to a portion of the bottom semiconductor layer. Also, the implanting of the at least one second amorphization implant species forms at least one amorphized region extending from the top surface of the DSB substrate to another portion of the bottom semiconductor layer.

Both the at least one first amorphization species and the at least one second implantation species may comprise any semiconductor material such as silicon, germanium, carbon, or other compound semiconductor material. The at least one second implantation species may be the same as or different from the at least one first implantation species. Preferably, the at least one second implantation species comprises the same material as the top semiconductor layer,

Preferably, another photoresist is applied prior to the lithographical patterning of the hard mask layer, wherein the photoresist prevents implantation of implant species into the top semiconductor layer outside the at least one opening during the implanting of the at least one first amorphization implant species. This photoresist is patterned with the STI pattern, which is subsequently transferred into the hard mask layer.

Lithographic patterning of the hard mask layer with a shallow trench isolation (STI) pattern may comprise:

forming a silicon oxide layer directly on the hard mask layer;

applying and lithographically patterning another photoresist on the silicon oxide layer with the STI pattern; and

transferring the STI pattern into the silicon oxide layer and then into the hard mask layer.

The thickness of the silicon oxide layer may be in the range from about 60 nm to about 200 nm, and preferably from about 90 nm to about 150 nm.

The method of forming a semiconductor structure according to the present invention may further comprise forming at least one pad layer directly on the top semiconductor layer, wherein the hard mask layer is formed directly on the at least one pad layer. Preferably, the at least one pad layer comprises a pad oxide layer.

The at least one pad layer may further comprise a polysilicon layer located directly on the pad oxide layer. Alternatively, the at least one pad layer may further comprise a silicon nitride layer located directly on the pad oxide layer.

According to the present invention, the method of forming a semiconductor structure may further comprise:

annealing the DSB substrate and converting at least one portion of the top semiconductor layer into a changed-orientation region that has the same crystallographic orientation as the bottom semiconductor layer; and

forming shallow trench isolation (STI) directly underneath the at least one opening in the hard mask layer.

The method of forming the shallow trench isolation directly underneath the at least one opening in the hard mask layer may farther comprise:

etching the top semiconductor layer and the bottom semiconductor layer underneath the at least one opening in the at least one hard mask layer to form STI region;

filling the STI region with at least one dielectric material; and

planarizing the at least one dielectric material.

The shallow trench isolation has trench walls that are substantially coincident with the at least one opening in the hard mask layer. The STI region coincides with the STI pattern.

### BRIEF DESCRIPTION OF THE DRAWINGS

FIGS. 1A-5A are sequential top-down views of an exemplary prior art structure in which trench-edge defect regions are formed on shallow trench isolation.

FIGS. 1B-5B are sequential cross-sectional views of the exemplary prior art structure along the plane of B-B′ in FIGS. 1A-5A.

FIGS. 6-18 are sequential vertical cross-sectional views of an exemplary semiconductor structure according to the present invention.

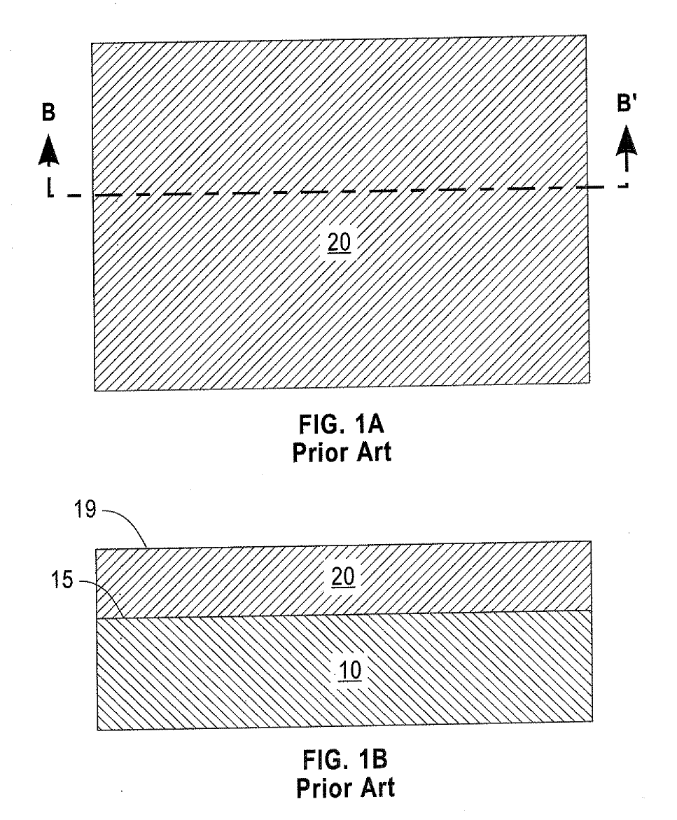

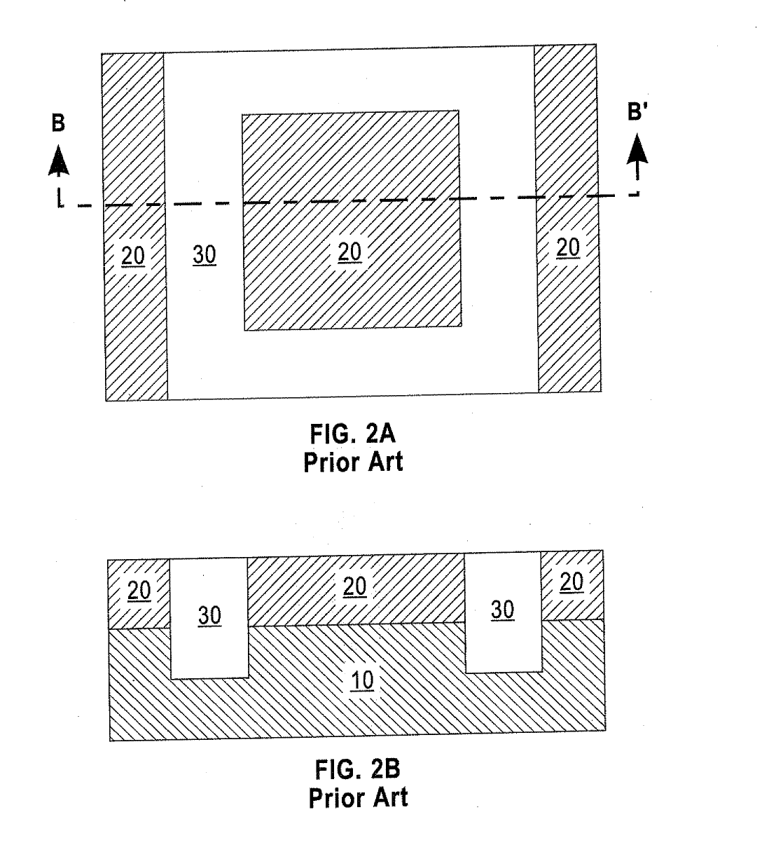

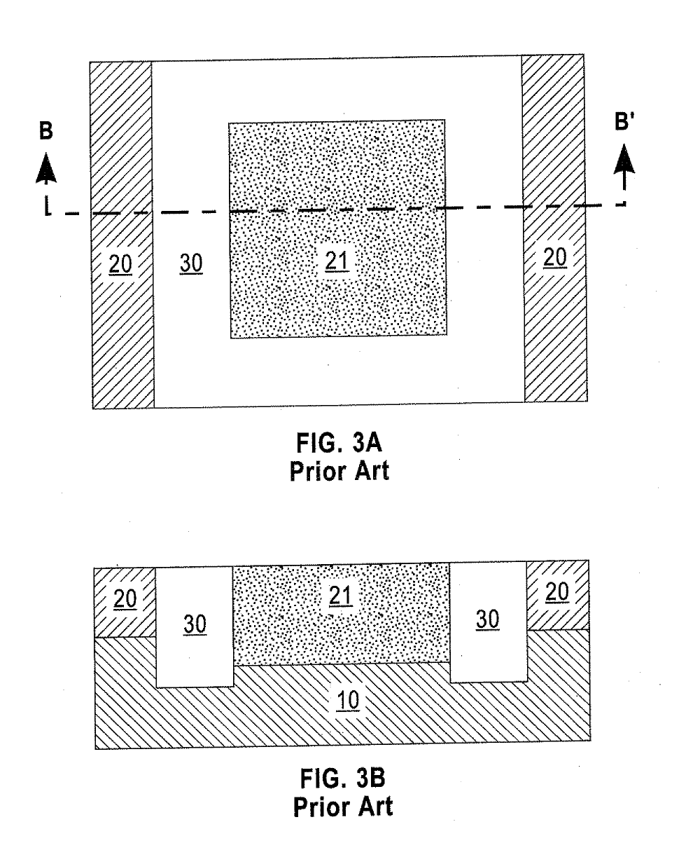

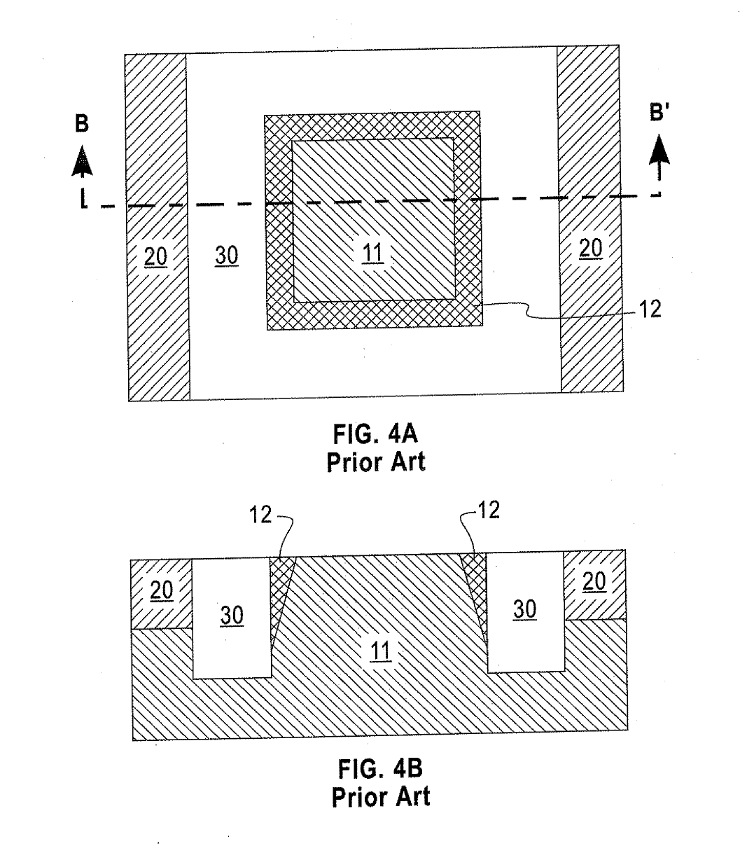

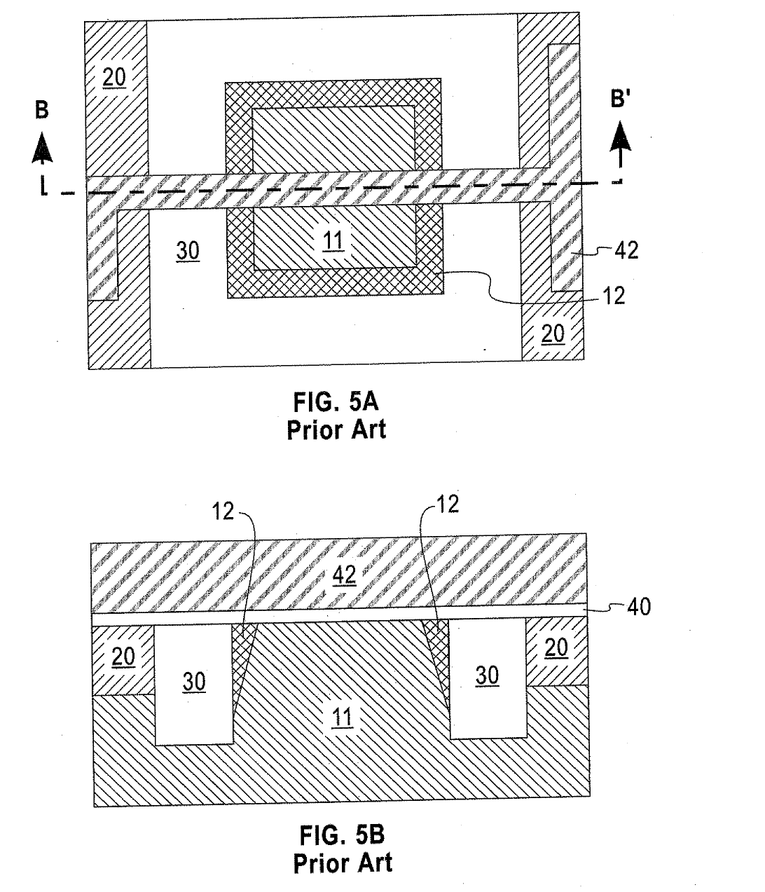

### DETAILED DESCRIPTION OF THE INVENTION

As stated above, the present invention relates to methods of manufacturing a semiconductor structure with shallow trench isolation that is self-aligned to templated recrystallization boundary in direct-semiconductor-bond substrates, which is now described in detail with accompanying figures.

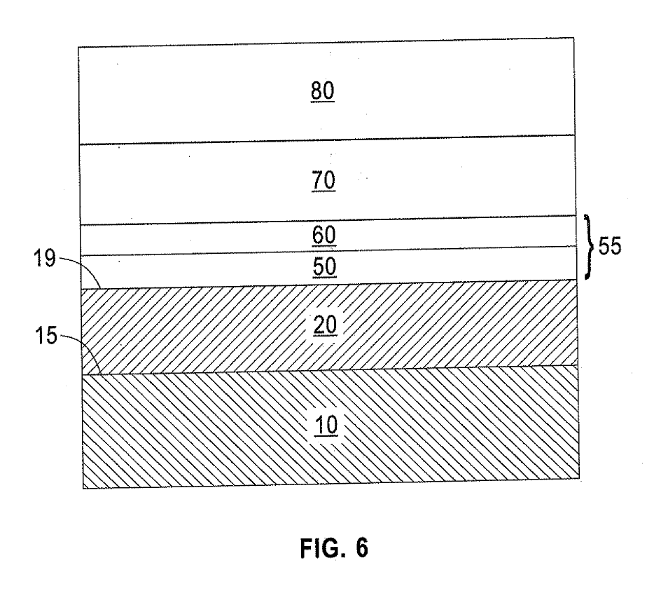

Referring to FIG. 6, a direct-semiconductor-bond (DSB) substrate comprises a bottom semiconductor layer 10, a top semiconductor layer 20, and a bonded interface 15 between the two semiconductor layers (10, 20). The top semiconductor layer 20 and the bottom semiconductor layer 10 have different surface orientations, that is, the crystallographic orientations in the direction of the surface normal of the outer surface 19 of the top semiconductor layer 20.

Each of the top semiconductor layer 20 and the bottom semiconductor layer 10 may comprise a semiconductor material selected from the group consisting of silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials. Both the top semiconductor layer 20 and the bottom semiconductor layer 10 may comprise a material with built-in strain. The bottom layer may, or may not, be disposed on an insulating layer

According to the present invention, the surface orientation of top semiconductor layer and the surface orientation of the bottom semiconductor layer are different. The surface orientation of each of the top semiconductor layer 20 and the bottom semiconductor layer 10 may be any crystallographic orientation, and preferably is one of major crystallographic orientations, and more preferably selected from the group consisting of (100), (110), (111), (211), (221), (311), and (331). In a first highly preferred embodiment, the surface orientation of the top semiconductor layer is (100) and the surface orientation of the bottom semiconductor layer is (110). In a second highly preferred embodiment, the surface orientation of the top semiconductor layer is (110) and the surface orientation of the bottom semiconductor layer is (100).

Optionally, zeroth-level (ZL) alignment marks may be formed in the top semiconductor layer 20 to facilitate alignment of lithographic patterns.

Optionally but preferably, at least one pad layer 55 is formed on the top surface 19 of the DSB substrate. The at least one pad layer 55 may comprise a stack of multiple layers. In FIG. 6, the at least one pad layer 55 comprises a first pad layer 50 which is formed directly on the top semiconductor layer 20 and a second pad layer 60 which is formed directly on the first pad layer 50. In a highly preferred embodiment of the present invention, the first pad layer 50 is a pad oxide layer and has a thickness in the range from about 3 nm to about 60 nm, and preferably in the range from about 6 nm to about 20 nm. In one embodiment, the second pad layer 60 may comprise a polysilicon layer and has a thickness in the range from about 50 nm to about 150 nm, and preferably in the range from about 60 nm to about 120 nm. In an alternative embodiment, the second pad layer 60 may be a silicon nitride layer and has a thickness in the range from about 10 nm to about 80 nm, and more preferably in the range from about 15 nm to about 40 nm. In a yet another embodiment, the at least one pad layer 55 may consist only of the first pad layer 50. The at least one pad layer 55 facilitates adhesion of a hard mask layer 70 to the top semiconductor substrate 20 and modulates the depth of at least one amorphization boundary region to be formed in at least one openings in the hard mask layer 70, as will be shown below.

According to the present invention, a hard mask layer 70 is deposited on the top semiconductor layer 20. The hard mask layer 70 may be formed directly on the top semiconductor layer 20, or alternatively and preferably, may be deposited directly on the at least one pad layer 55, which is formed directly on the top semiconductor layer 20.

The hard mask layer 70 may be selected from the group consisting of a silicon nitride layer, a silicon oxide layer, a polysilicon layer, an amorphous silicon layer, a polycrystalline silicon containing alloy, and an amorphous silicon containing alloy. In one embodiment, the hard mask layer 70 is a silicon nitride layer and has a thickness in the range from about 10 nm to about 80 nm, and more preferably in the range from about 15 nm to about 40 nm. In another embodiment, the hard mask layer 70 is a polysilicon layer and has a thickness in the range from about 50 nm to about 150 nm, and preferably in the range from about 60 nm to about 120 nm. Preferably, the material of the layer directly underneath the hard mask layer 70 has a different composition than the hard mask layer 70 to provide etch selectivity during subsequent patterning of the hard mask layer 70.

Not necessarily, but preferably, a silicon oxide layer 80 is formed directly on the hard mask layer 70. The thickness of the silicon oxide layer may be in the range from about 60 nm to about 200 nm, and preferably from about 90 nm to about 150 nm.

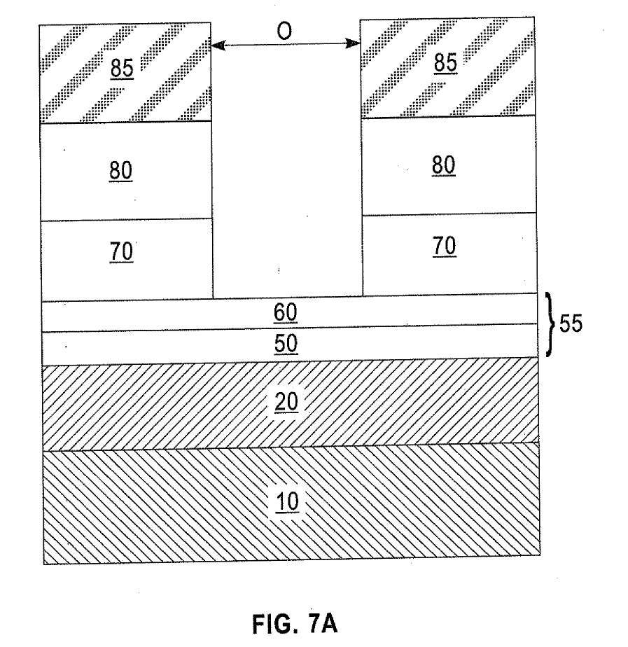

Referring to FIGS. 7A and 7B, a first photoresist 85 is applied either to the surface of the hard mask layer 70 or to the surface of the silicon oxide layer 80 and lithographically patterned with a shallow trench isolation (STI) pattern. The thickness of the first photoresist 85 is in the range from about 200 nm to about 800 nm, and typically in the range from about 300 nm to about 600 nm. The STI pattern in the first photoresist 85 contains at least one opening O which corresponds to the STI region to be subsequently formed. If zeroth-level (ZL) alignment marks were formed in the top semiconductor layer 20, the STI pattern may be aligned to the ZL alignment marks. In a preferred embodiment of the present invention, the silicon oxide layer 80 is located directly on the hard mask layer 70, as shown in FIG. 7A. The first photoresist 85 is applied directly on the silicon oxide layer 80 and patterned with the STI pattern. The STI pattern is then transferred into the silicon oxide layer 80 and into the hard mask layer 80. In an alternate embodiment of the present invention, a silicon oxide layer 80 is not present in the structure, as shown in FIG. 7B. The first photoresist 85 is applied directly on the hard mask layer 70 and the STI pattern in the first photoresist 85 is directly transferred from the first photoresist 85 into the hard mask layer 70.

In both embodiments of the present invention, if the at least one pad layer 55 is present in the semiconductor structure, the reactive ion etch is preferably selective to the underlying at least one pad layer 55. If the hard mask layer 70 is formed directly on the top semiconductor layer 20, the reactive ion etch is selective to the material in the top semiconductor layer 20.

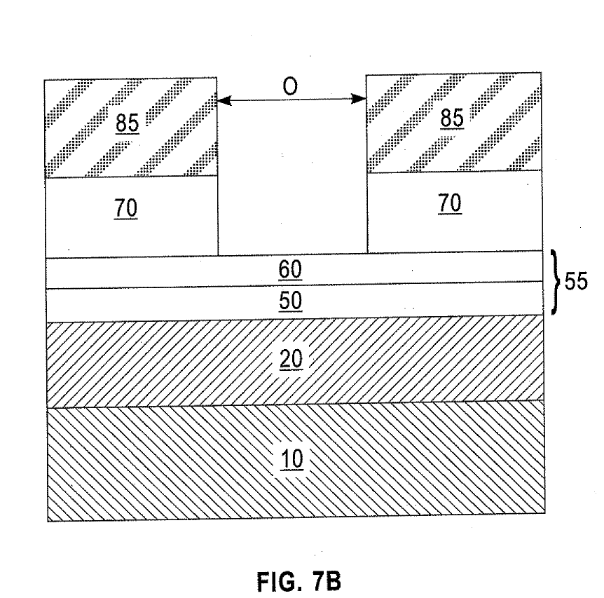

Referring to FIGS. 8A and 8B, at least one first amorphization implant species is implanted through the at least one opening O in the first photoresist 85 and in the hard mask layer 70 as shown in FIGS. 8A and 8B. The at least one first amorphization implant species is implanted into the top semiconductor layer 20 and into upper portions of the bottom semiconductor layer 10 to amorphize the semiconductor material therein. A region comprising amorphized semiconductor material, or an “amorphization boundary region” 21 is formed underneath each opening O in the first photoresist 85 and in the hard mask layer 70. Therefore, at least one amorphization boundary region 21 is formed in the DSB substrate corresponding to the at least one opening O in the STI pattern. The pattern formed by the at least one amorphization boundary region 21 is identical to the STI pattern.

The at least one first amorphization implant species is selected from semiconductor material such as silicon, germanium, carbon, and other compound semiconductor material. Preferably, the at least one first implantation species comprises the same material as the top semiconductor layer.

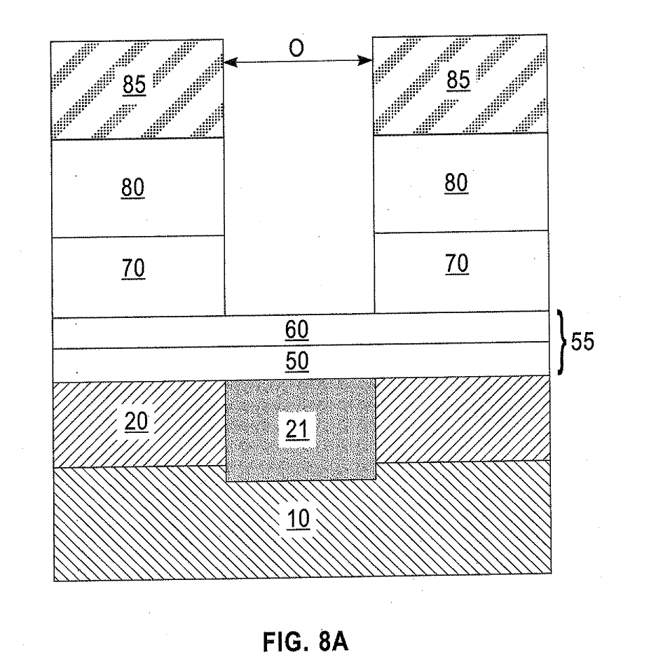

Referring to FIG. 9, the first photoresist 85 is thereafter removed according to both embodiments of the present invention. Preferably, the silicon oxide layer 80 is also removed according to the alternate embodiment of the present invention.

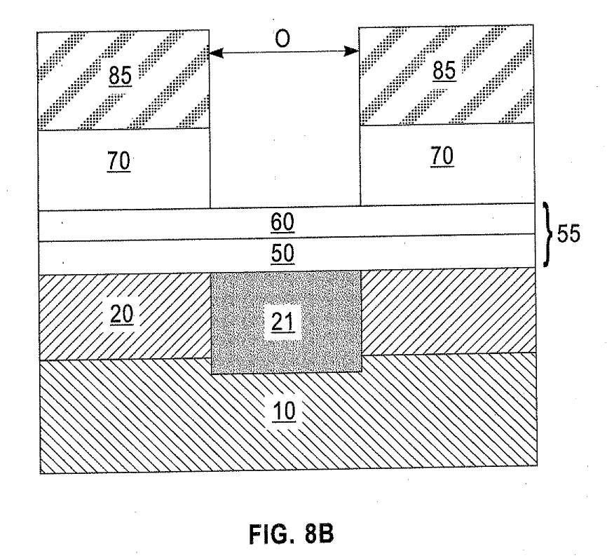

Referring to FIG. 10, a second photoresist 75 is applied to the surface of the hard mask layer 70 and over the exposed portions of the top semiconductor layer 20, and lithographically patterned to define a region within the top semiconductor layer 20 in which the surface orientation of the top surface 19 of the DSB substrate is to be changed to the surface orientation of the bottom semiconductor layer 10, i.e., a “changed-orientation region.” A region of the top semiconductor layer 20 in which the surface orientation of the top surface 19 of the DSB substrate is to remain the same is defined as an “original-orientation region.” The second photoresist 75 remains over the “changed-orientation region” but is absent in the “original-orientation region” after the patterning of the second photoresist 75.

According to the present invention, at least one edge of the second photoresist 75 is located within the at least one opening O in the hard mask layer 70. Preferably, as many edges of the second photoresist 75, and more preferably, all edges of the second photoresist 75 are located within the at least one opening O in the hard mask layer 70. By aligning the edges of the second photoresist 75 with the patterns of the at least one opening O in the hard mask layer 70, the boundaries of the changed-orientation region to be subsequently formed are also aligned to the pattern of the at least one opening O, which is identical to the STI pattern. Therefore, alignment of the changed-orientation region to be subsequently formed to the preexisting STI pattern occurs during the alignment of the pattern in the second photoresist 75 with the STI pattern on the hard mask layer 70 at this processing step.

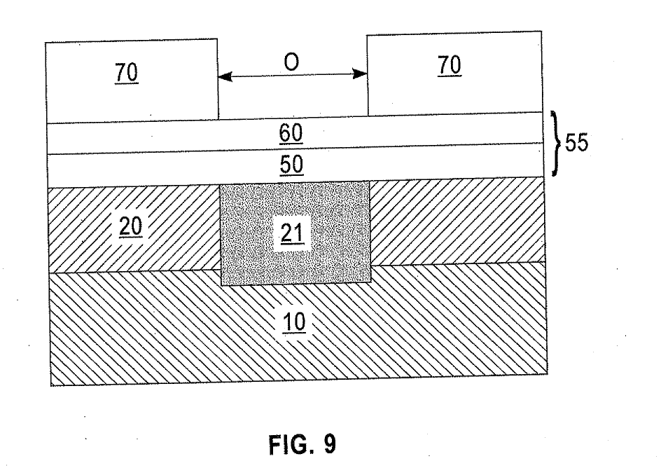

Referring to FIG. 11, at least one second amorphization implant species is implanted into portions of the top semiconductor layer 10 that is not covered with the second photoresist 75. The at least one second amorphization implant species is selected from semiconductor material such as silicon, germanium, carbon, and other compound semiconductor material. The at least one second amorphization implant species may be the same as or different from the at least one first amorphization implant species. Preferably, the at least one amorphization species comprises the same material as the top semiconductor layer 20.

At least one amorphized region 22, extending from a top surface 19 of the DSB substrate to at least a portion of the bottom semiconductor layer 10, is formed in the DSB substrate. The at least one amorphized region 22 comprises at least one second-implant amorphized region 22′, which is amorphized only by the at least one second amorphization implant species, and at least one dual-implant amorphized region 21″, which was amorphized during the amorphization implantation with the at least one first amorphization implant species and subsequently implanted with the at least one second amorphization implant species. At this point, the at least one amorphization boundary region 21 comprises at least one first-implant amorphized region 21′, which was amorphized during the amorphization implantation with the at least one first amorphization implant species but is not implanted with the at least one second amorphization implant species, and the at least one dual-implant amorphized region 21″.

The “changed-orientation region” to be subsequently formed is at this point implanted with the at least one second amorphization implant species. The at least one second amorphization implant species is selected from semiconductor material such as silicon, germanium, carbon, and other compound semiconductor material. Preferably, the at least one second implantation species comprises the same material as the top semiconductor layer 20.

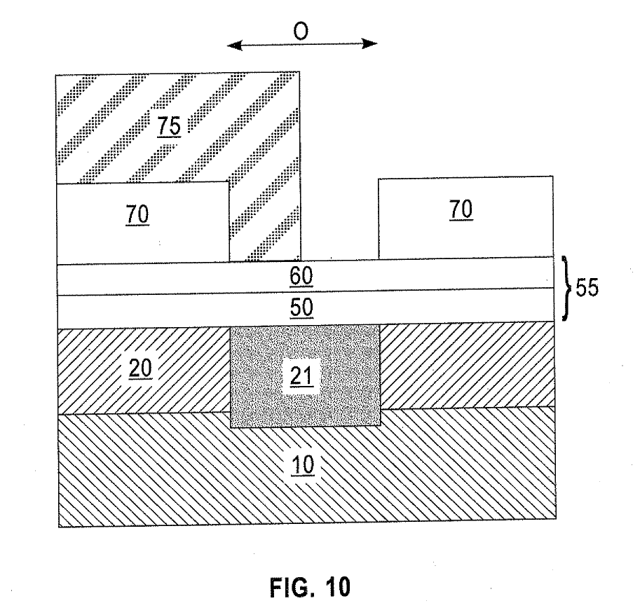

Referring to FIG. 12, the second photoresist 75 is removed. At least one “extended amorphized region” 23, or at least one collection of all contiguous amorphized regions, comprises the at least one first-implant amorphized region 21′, the at least one dual-implant amorphized region 21″, and the at least one second-implant amorphized region 22′ that are contiguous with one another. The semiconductor material within each of the at least one extended amorphized region 23 is amorphous.

A templated recrystallization process is thereafter employed to convert the at least one extended amorphized region 23 into crystalline structures. The templated recrystallization process preferably employs solid phase epitaxy (SPE). Various methods of solid phase epitaxy may be employed for the purposes of the present invention. These include a conventional anneal in a furnace, a rapid thermal anneal, a flash anneal, and a laser anneal. While the mechanism of anneal is thermally dominated, selection of a particular anneal method typically places limits on the temperature range for the anneal method. Typical temperature ranges for the anneal processes are from about 650° C. to about 1000° C. for solid phase epitaxy through an anneal in a furnace, from about 650° C. to about 1200° C. for solid phase epitaxy through a rapid thermal anneal, and from about 700° C. to about 1428° C. for solid phase epitaxy through a laser anneal. Since the mechanism of the process of solid phase epitaxy is primarily temperature dependent, the anneal time is mostly determined by the temperature for a given thickness of an amorphized region. Typically, the anneal time is in the range of 1 hour near the low temperature limit and approaches several seconds or even milliseconds near the upper temperature limit. Through the process of solid phase epitaxy, the at least one extended amorphized region 23 is regrown into crystalline semiconductor regions.

Two templates for recrystallization with two different surface orientations, i.e., the crystalline bottom semiconductor layer 10 and the crystalline top semiconductor layer 20, and consequently two different crystallographic orientations, are present on the surface of the at least one extended amorphized region 23. Therefore, at least two different portions with different crystallographic orientations are formed within at least one “recrystallized region” that is derived from the at least one extended amorphized region 23.

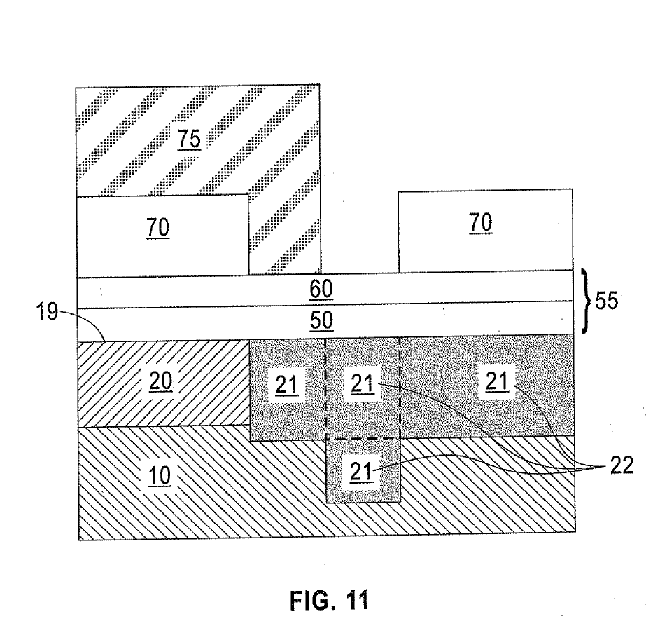

Referring to FIG. 13, the original bottom semiconductor layer 10 and the portions of the at least one recrystallized region that are epitaxially aligned to the original bottom semiconductor layer 10 form an extended bottom semiconductor layer 11. The top semiconductor layer 20 “grows” by epitaxial alignment of a portion of the at least one extended amorphized region 23 from the outer edges. At least one defect boundary region 14 is formed between the extended bottom semiconductor layer 11 and the top semiconductor layer 20 beneath the top surface 19 of the DSB substrate. Similar to trench-edge defects, the at least one defect boundary region 14 comprises crystalline defects, which provides a leakage path for high performance semiconductor devices and degrades their performance as discussed above.

The structure of the at least one defect boundary region 14 is an exemplary case, in which the extended bottom semiconductor layer 11 has a (001) substrate orientation, the top semiconductor layer 20 has a (011) substrate orientation, and the defect boundary region is formed around a interface between an (110) plane of the bottom semiconductor layer 11 and an (100) plane of the top semiconductor layer 20 that are coincident underneath the opening O. It is understood that the shape of the at least one boundary region depends on the crystallographic orientations of the extended bottom semiconductor layer 11 and the top semiconductor layer 20 as well as the geometry of the opening O and recrystallization anneal processes.

According to the present invention, the location of the at least one defect boundary region 14 is determined not by the edges of the second photoresist 75 but by the edges of the first photoresist 85, which defines the STI pattern. Therefore, the location of the at least one defect boundary region is self-aligned to the STI pattern in the first photoresist 85.

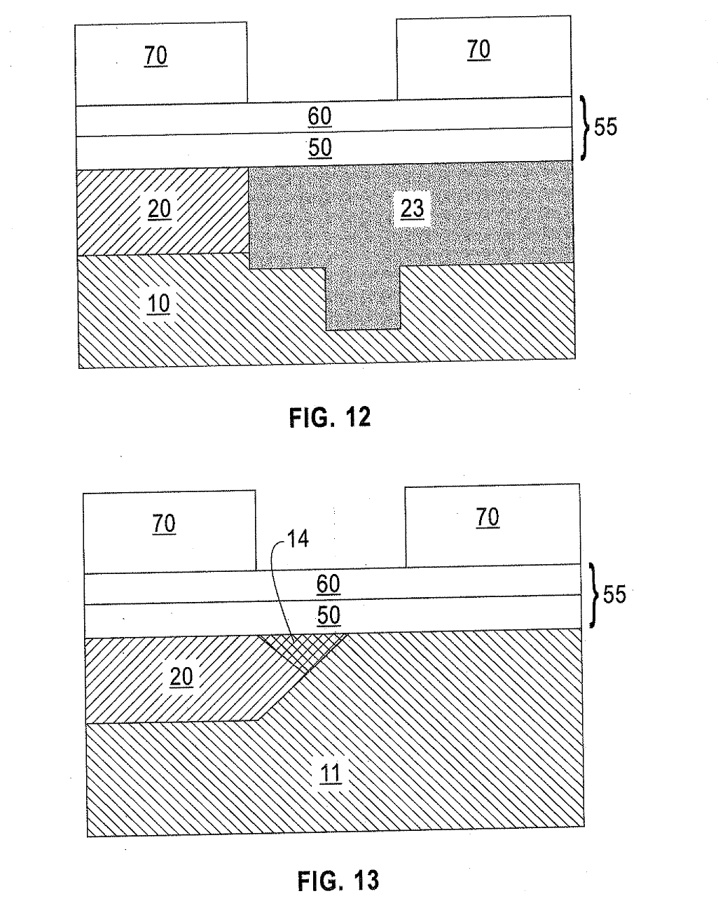

Referring to FIG. 14, portions of the DSB substrate beneath the at least one opening O in the hard mask layer 70, which include the at least one defect boundary region 14, at least a portions of the top semiconductor layer 20, and at least a portion of the extended bottom semiconductor layer 11, are etched to a depth deeper than the bonded interface 15. Since the at least one opening O in the hard mask layer 70 has the STI pattern that is transferred from the first photoresist 75, the etched portions of the DSB substrate also has the STI pattern. Thus, the etched portions of the DSB substrate form shallow trenches for the STI region. Since all of the at least one defect boundary region 14 is located within the at least one opening O, the etch process removes all of the at least one defect boundary region 14 from the DSB substrate according to the present invention.

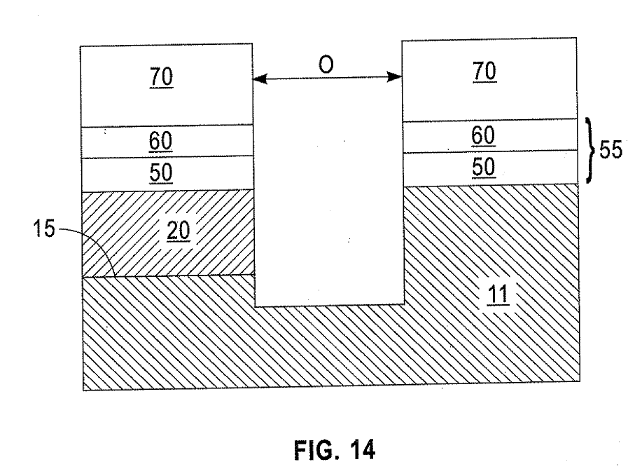

Referring to FIG. 15, the shallow trenches of the STI region is filled with at least one dielectric material 30. The at least one dielectric material 30 preferably comprises an oxide material, and more preferably a silicon oxide. A dielectric liner may be formed on surface of the STI region prior to filling of the STI region. The at least one dielectric material 30 may be deposited by chemical vapor deposition (CVD).

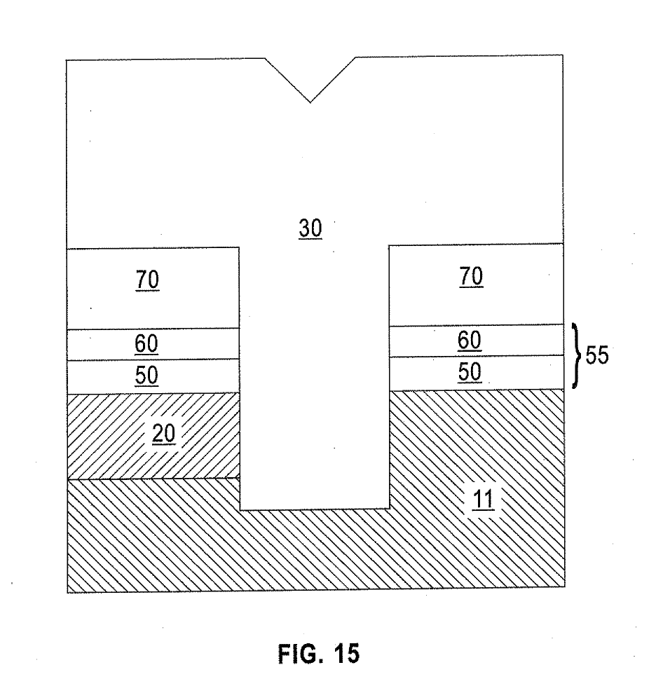

Referring to FIG. 16, the at least one dielectric material 30 is planarized by chemical mechanical planarization (CMP) to form shallow trench isolation (STI) 30′. At the end of planarization, the surface of the STI 30′ is coplanar with the hard mask layer 70.

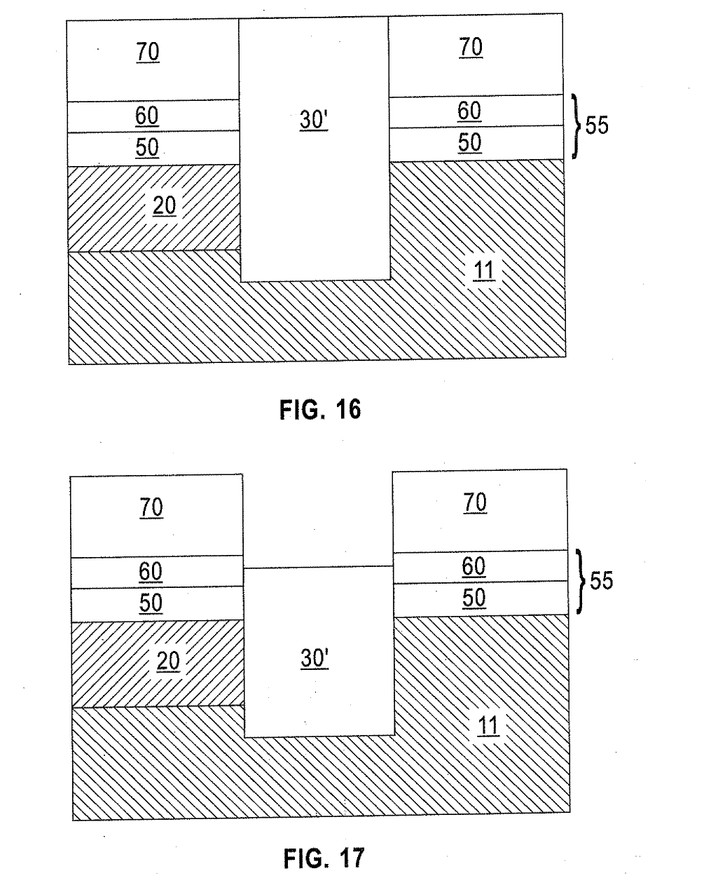

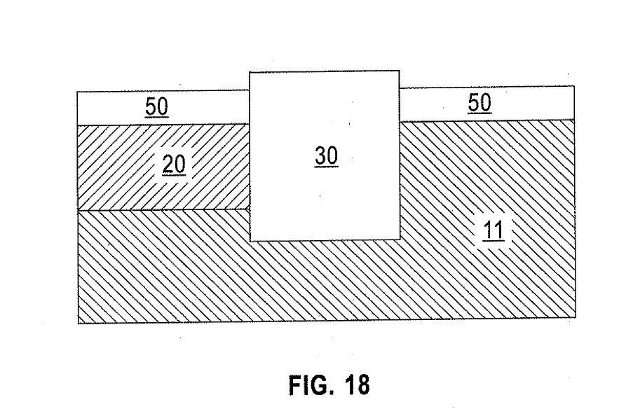

Referring to FIG. 17, optionally and preferably, the STI 30′ may be recessed to an optimal depth. The hard mask layer 70 is thereafter removed. Some of the at least one pad layer 55, for example, the second pad layer 60 may be removed thereafter as shown in FIG. 18.

While the invention has been described in terms of specific embodiments, it is evident in view of the foregoing description that numerous alternatives, modifications and variations will be apparent to those skilled in the art. Accordingly, the invention is intended to encompass all such alternatives, modifications and variations which fall within the scope and spirit of the invention and the following claims.

What is claimed is:

1. A method of forming a semiconductor structure comprising:
providing a direct-semiconductor-bond (DSB) substrate containing a top semiconductor layer with a first surface orientation and a bottom semiconductor layer with a second surface orientation:
forming a hard mask layer on said top semiconductor layer;
lithographically patterning said hard mask layer with a shallow trench isolation (STI) pattern, wherein said STI pattern contains at least one opening;
implanting at least one first amorphization implant species into said top semiconductor layer through at least one opening in said hard mask layer;
applying and lithographically patterning a photoresist on said DSB substrate, wherein at least one edge of said photoresist is located within said at least one opening in said hard mask layer; and
implanting at least one second amorphization implant species into portions of said top semiconductor layer that is not covered with said photoresist.

2. The method of claim 1, wherein said lithographical patterning of said photoresist on said DSB substrate is aligned to said STI pattern in said hard mask layer.

3. The method of claim 1, wherein said implanting of said at least one first amorphization implant species forms at least one amorphization boundary region extending from a top surface of said DSB substrate to a portion of said bottom semiconductor layer.

4. The method of claim 1, wherein said implanting of said at least one second amorphization implant species forms at least one amorphized region extending from a top surface of said DSB substrate to another portion of said bottom semiconductor layer.

5. The method of claim 4, wherein said at least one second implantation species comprises the same material as said top semiconductor layer.

6. The method of claim 1, further comprising applying another photoresist prior to said lithographical patterning of said hard mask layer, wherein said another photoresist prevents implantation of implant species into said top semiconductor layer outside said at least one opening during said implanting of said at least one first amorphization implant species.

7. The method of claim 1, wherein said hard mask layer is selected from the group consisting of a silicon nitride layer, a silicon oxide layer, a polysilicon layer, an amorphous silicon layer, a polycrystalline silicon containing alloy, and an amorphous silicon containing alloy.

8. The method of claim 1, wherein each of said top semiconductor layer and said bottom semiconductor layer comprises a semiconductor material selected from the group consisting of silicon, germanium, silicon-germanium alloy, silicon carbon alloy, silicon-germanium-carbon alloy, gallium arsenide, indium arsenide, indium phosphide, III-V compound semiconductor materials, II-VI compound semiconductor materials, organic semiconductor materials, and other compound semiconductor materials.

9. The method of claim 1, further comprising:
forming a silicon oxide layer directly on said hard mask layer;
applying and lithographically patterning another photoresist on said silicon oxide layer with said STI pattern; and
transferring said STI pattern into said silicon oxide layer and then into said hard mask layer.

10. The method of claim 9, wherein the thickness of said silicon oxide layer is in the range from about 60 nm to about 200 nm.

11. The method of claim 1, further comprising forming at least one pad layer directly on said top semiconductor layer, wherein said hard mask layer is formed directly on said at least one pad layer.

12. The method of claim 11, wherein said at least one pad layer comprises a pad oxide layer, wherein said pad oxide layer is located directly on said top semiconductor layer and has a thickness in the range from about 3 nm to about 60 nm.

13. The method of claim 12, wherein said at least one pad layer further comprises a polysilicon layer located directly on said pad oxide layer and has a thickness in the range from about 50 nm to about 150 nm.

14. The method of claim 12, wherein said at least one pad layer further comprises a silicon nitride layer located directly on said pad oxide layer and has a thickness in the range from about 10 nm to about 80 nm.

15. The method of claim 1, wherein the surface orientation of each of said top semiconductor layer and said bottom semiconductor layer is selected from the group consisting of (100), (110), (111), (211), (221), (311), and (331).

16. The method of claim 14, wherein the surface orientation of said top semiconductor layer is (100) and the surface orientation of said bottom semiconductor layer is (110).

17. The method of claim 14, wherein the surface orientation of said top semiconductor layer is (110) and the surface orientation of said bottom semiconductor layer is (100).

18. The method of claim 1, further comprising:
annealing said DSB substrate and converting at least one portion of said top semiconductor layer into a changed-orientation region that has the same crystallographic orientations as said bottom semiconductor layer; and
forming shallow trench isolation (STI) directly underneath said at least one opening in said hard mask layer.

19. The method of claim 18, further comprising:
etching said top semiconductor layer and said bottom semiconductor layer underneath said at least one opening in said at least one hard mask layer to form STI region;
filling said STI region with at least one dielectric material; and
planarizing said at least one dielectric material.

20. The method of claim 18, wherein said shallow trench isolation has trench walls that are substantially coincident with said at least one opening in said hard mask layer.
